(19) United States
(12) Patent Application Publication
(10) Pub. No.: US 2014/0155618 A1
(43) Pub. Date: Jun. 5, 2014

(54) CHARGE TRANSPORT MATERIAL FOR ORGANIC ELECTROLUMINESCENCE DEVICE AND ORGANIC ELECTROLUMINESCENCE DEVICE INCLUDING THE SAME

(71) Applicant: SAMSUNG DISPLAY CO., LTD., Yongin-City (KR)

(72) Inventor: Junta FUCHIWAKI, Yongin-City (KR)

(73) Assignee: SAMSUNG DISPLAY CO., LTD., Yongin-City (KR)

(21) Appl. No.: 14/089,848

(22) Filed: Nov. 26, 2013

(30) Foreign Application Priority Data
Nov. 30, 2012 (JP) 2012-261933

(51) Int. Cl. H01L 51/00

(52) U.S. Cl. CPC H01L 51/0067; H01L 51/0072
USPC 548/255

(57) ABSTRACT

A charge transport material includes a combined structure obtained by condensing a compound represented by (1) and a compound represented by (2), and combining the compound represented by (2) and a compound represented by (3) with an Ar included in the compound represented by (2) therebetween, in following Formula 1,

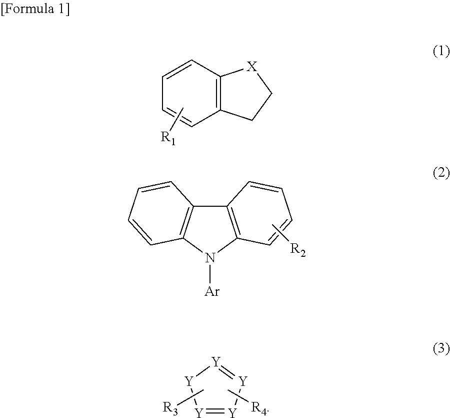

### CROSS-REFERENCE TO RELATED APPLICATION

Japanese Patent Application No. 2012-261933, filed on Nov. 30, 2012, in the Japanese Patent Office, and entitled: “Charge Transport Material for Organic Electroluminescence Device and Organic Electroluminescence Device comprising the Same,” is incorporated by reference herein in its entirety.

### BACKGROUND

1. Field

Embodiments relate a charge transport material for an organic electroluminescence device and an organic electroluminescence device using the same.

2. Description of the Related Art

In recent years, organic electroluminescence (EL) displays that are one type of image displays have been actively developed. Unlike a liquid crystal display and the like, the organic EL display is so-called a self-luminescent display which recombines holes and electrons injected from a positive electrode and a negative electrode in an emission layer to thus emit a light from a light-emitting material including an organic compound of the emission layer, thereby performing display.

### SUMMARY

Embodiments are directed to a charge transport material for an organic electroluminescence device, including a combined structure obtained by condensing a skeleton represented by compound (1) and a skeleton represented by compound (2), and combining the skeleton represented by compound (2) and a skeleton represented by compound (3) with an Ar included in the skeleton represented by compound (2) therebetween, in following Formula 1,

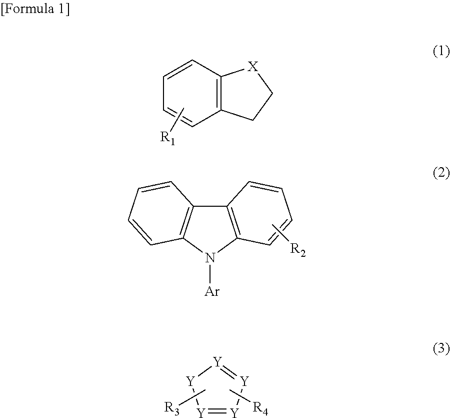

In compound (1), X may be oxygen, sulfur, or nitrogen combined with a substituted or unsubstituted, and straight or branched alkyl group, an aromatic group, or a heteroaromatic group having 1 to 10 carbon atoms, R₁ may be a substituted or unsubstituted, and straight or branched alkyl group, an aromatic group or a heteroaromatic group having 1 to 10 carbon atoms, Ar in compound (2) may be a single bond, a substituted or unsubstituted arylene group, or a heteroarylene group, and R₂ may be a substituted or unsubstituted, and straight or branched alkyl group, an aromatic group or a heteroaromatic group having 1 to 10 carbon atoms, Y in compound (3) may be a carbon atom or a nitrogen atom, Y may include at least 3 nitrogen atoms, each of R₃ and R₄ may independently represent a substituted or unsubstituted, and straight or branched alkyl group, an aromatic group or a heteroaromatic group having 1 to 10 carbon atoms, or a hydrogen atom, a number of R₁ may be 0 to 4, a number of R₂ may be 0 to 6, and R₂ may be combined with one ring or both rings among two benzene rings of compound (2).

R₃ and R₄ in compound (3) may represent a phenyl group combined with the carbon or the nitrogen represented by the Ys.

Three of the Ys in compound (3) may be the nitrogen atoms, and the nitrogen atoms may be adjacent to each other.

Embodiments are also directed to an organic electroluminescence device including an emission layer formed by using a charge transport material for an organic electroluminescence device according to an embodiment. The charge transport material may include a combined structure obtained by condensing a skeleton represented by compound (4) and a skeleton represented by compound (5), and combining the skeleton represented by compound (5) and a skeleton represented by compound (6) with an Ar included in the skeleton represented by compound (5) therebetween, in following Formula 2,

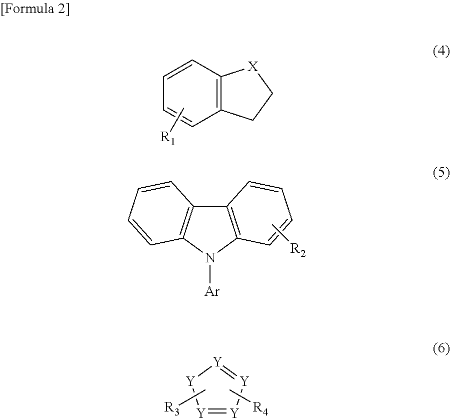

In compound (4), X may be oxygen, sulfur, or nitrogen combined with a substituted or unsubstituted, and straight or branched alkyl group, an aromatic group, or a heteroaromatic group having 1 to 10 carbon atoms, R₁ may be a substituted or unsubstituted, and straight or branched alkyl group, an aromatic group or a heteroaromatic group having 1 to 10 carbon atoms, Ar in compound (5) may be a single bond, a substituted or unsubstituted arylene group, or a heteroarylene group, and R₂ may be a substituted or unsubstituted, and straight or branched alkyl group, an aromatic group or a heteroaromatic group having 1 to 10 carbon atoms, Y in compound (6) may be a carbon atom or a nitrogen atom, Y may include at least 3 nitrogen atoms, each of R₃ and R₄ may independently represent a substituted or unsubstituted, and straight or branched alkyl group, an aromatic group or a heteroaromatic group having 1 to 10 carbon atoms, or a hydrogen atom, a number of R₁ may be 0 to 4, a number of R₂ may be 0 to 6, and R₂ may be combined with one ring or both rings among two benzene rings of compound (5).

R₃ and R₄ in compound (6) may represent a phenyl group combined with the carbon or the nitrogen represented by the Ys.

Three of the Ys in compound (6) may be the nitrogen atoms, and the nitrogen atoms may be adjacent to each other.

### BRIEF DESCRIPTION OF THE DRAWINGS

Features will become apparent to those of skill in the art by describing in detail exemplary embodiments with reference to the attached drawing in which:

FIG. 1 is a schematic diagram illustrating an organic EL device according to an example embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

An example embodiment may provide an organic EL device having good charge transport properties, high efficiency, and long life. The organic EL device may include an emission layer using a charge transport material including a compound having an indolocarbazole skeleton with an azole skeleton having at least 3 nitrogen atoms.

According to an example embodiment, a charge transport material for an organic EL device is a compound having an indolocarbazole skeleton with an azole skeleton having at least 3 nitrogen atoms. Thus, the charge transport material for an organic EL device may have a combined structure of an indolocarbazole and an azole with a single bond or a linker therebetween.

According to an example embodiment, the charge transport material for an organic EL device includes a combined structure obtained by condensing a compound represented by (7) and a compound represented by (8), and combining the compound represented by (8) and a compound represented by (9) with an Ar included in the compound represented by (8) therebetween, in the following Formula 3,

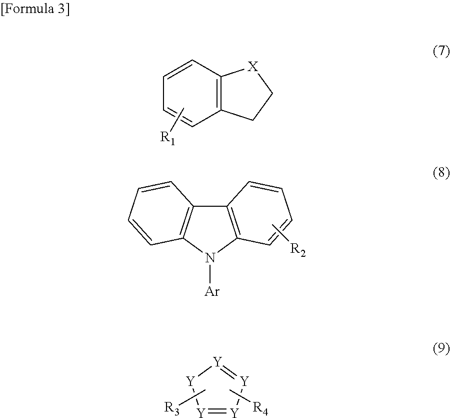

Six isomers of the indolocarbazole may be formed according to the above. The structures of the isomers are not specifically limited in the charge transport material for an organic EL device. Therefore, the skeleton of the indolocarbazole may be generalized as a cyclized structure by combining compound (7) and compound (8) in the charge transport material for an organic EL device.

According to an example embodiment, in compound (7), X is oxygen, sulfur, or nitrogen combined with a substituted or unsubstituted, and straight or branched alkyl group, an aromatic group, or a heteroaromatic group having 1 to 10 carbon atoms, R₁ is a substituted or unsubstituted, and straight or branched alkyl group, an aromatic group or a heteroaromatic group having 1 to 10 carbon atoms. Ar in compound (8) is a single bond, a substituted or unsubstituted arylene group, or a heteroarylene group, and R₂ is a substituted or unsubstituted, and straight or branched alkyl group, an aromatic group or a heteroaromatic group having 1 to 10 carbon atoms.

According to the present example embodiment, the azole is represented by compound (9). In the azole of compound (9), Y is a carbon atom or a nitrogen atom, Y includes at least 3 nitrogen atoms, each of R₃ and R₄ independently represents a substituted or unsubstituted, and straight or branched alkyl group, an aromatic group or a heteroaromatic group having 1 to 10 carbon atoms, or a hydrogen atom. In compound (9) according to the present example embodiment, R₃ and R₄ may represent a phenyl group combined with the carbon or the nitrogen represented by Y. In an example embodiment, the indolocarbazole may be combined by using an azolotriazole. A compound including a triazole skeleton may have a high triplet T1 energy. Thus, light-emitting efficiency may be increased. In an example embodiment, an indolocarbazole including 1,2,3-triazole skeleton in which three adjacent Y are nitrogen atoms may be used as the charge transport material for forming an emission layer.

According to an example embodiment, the charge transport material for an organic EL device may be obtained by combining an indolocarbazole skeleton having good hole transport properties and an azole skeleton having good electron transport properties by including a nitrogen atom having high electron affinity. Thus, an emission layer having good properties such as the lowering of the voltage of a device, may be formed. In addition, the compound including the triazole skeleton may have high triplet T1 energy. Thus, light-emitting efficiency may be improved. The organic EL device including the emission layer formed by using the charge transport material for an organic EL device may have a low driving voltage, and high efficiency may be realized. In addition, longer life may be obtained when compared to a general device.

A combined compound of indolocarbazole and triazine which is a 6-member ring of C₃N₃ may be considered. However, the manufacture of a homogeneous amorphous layer using the compound including the 6-member ring may be difficult. Due to the high planarity of a skeleton including triazine in a compound including triazine, molecules may be easily stacked in parallel. In addition, a 6-member ring including nitrogen may have high coordination ability. Thus, decomposition of a metal complex dopant may occur.

According to an example embodiment, the triazole in the charge transport material for an organic EL device has an asymmetric structure, and an adjacent aryl group may be twisted by steric hindrance, and the planarity may be lowered. Accordingly, crystallization of the charge transport material of an organic EL device may be difficult, and the formation of a homogeneous amorphous layer may be enabled. Thus, the charge transport material according to an example embodiment may be appropriately used for forming the emission layer.

According to an example embodiment, the charge transport material for an organic EL device may include, for example, the materials represented by the following Formula 4,

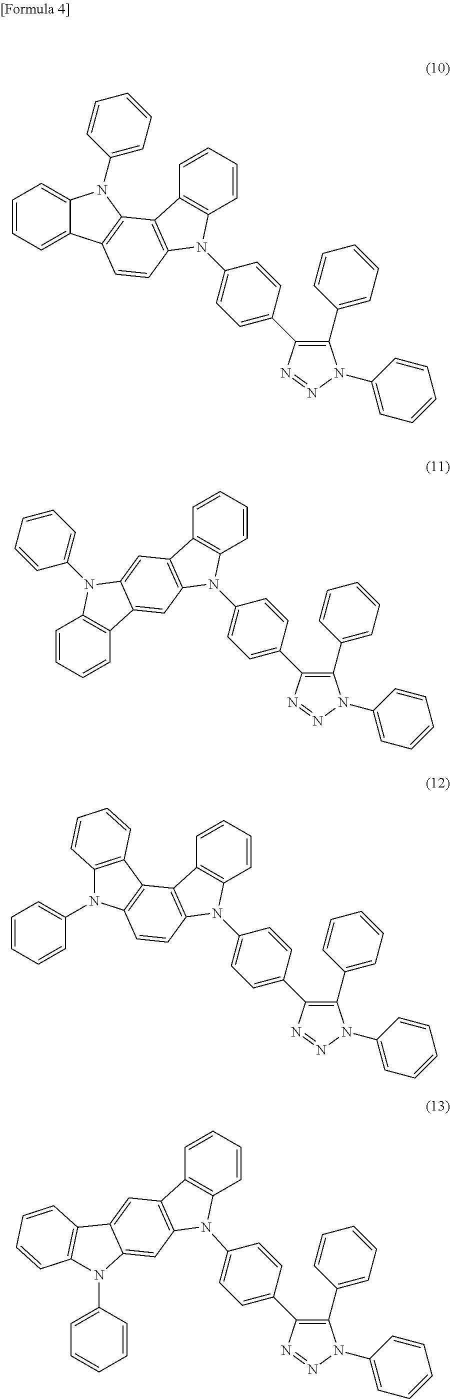 [SMILES: c1ccc(-c2c(-c3ccc(-n4c5ccccc5c5c4ccc4c6ccccc6n(-c6ccccc6)c45)cc3)nnn2-c2ccccc2)cc1 ; c1ccc(-c2c(-c3ccc(-n4c5ccccc5c5cc6c(cc54)c4ccccc4n6-c4ccccc4)cc3)nnn2-c2ccccc2)cc1 ; c1ccc(-c2c(-c3ccc(-n4c5ccccc5c5c6c7ccccc7n(-c7ccccc7)c6ccc54)cc3)nnn2-c2ccccc2)cc1 ; c1ccc(-c2c(-c3ccc(-n4c5ccccc5c5cc6c7ccccc7n(-c7ccccc7)c6cc54)cc3)nnn2-c2ccccc2)cc1]

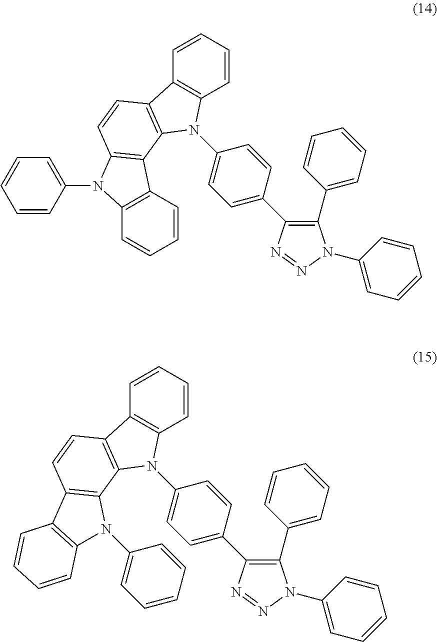 [SMILES: c1ccc(-c2c(-c3ccc(-n4c5ccccc5c5ccc6c(c7ccccc7n6-c6ccccc6)c54)cc3)nnn2-c2ccccc2)cc1 ; c1ccc(-c2c(-c3ccc(-n4c5ccccc5c5ccc6c7ccccc7n(-c7ccccc7)c6c54)cc3)nnn2-c2ccccc2)cc1]

According to an example embodiment, the charge transport material for an organic EL device may include, for example, the materials represented by the following Formula 5,

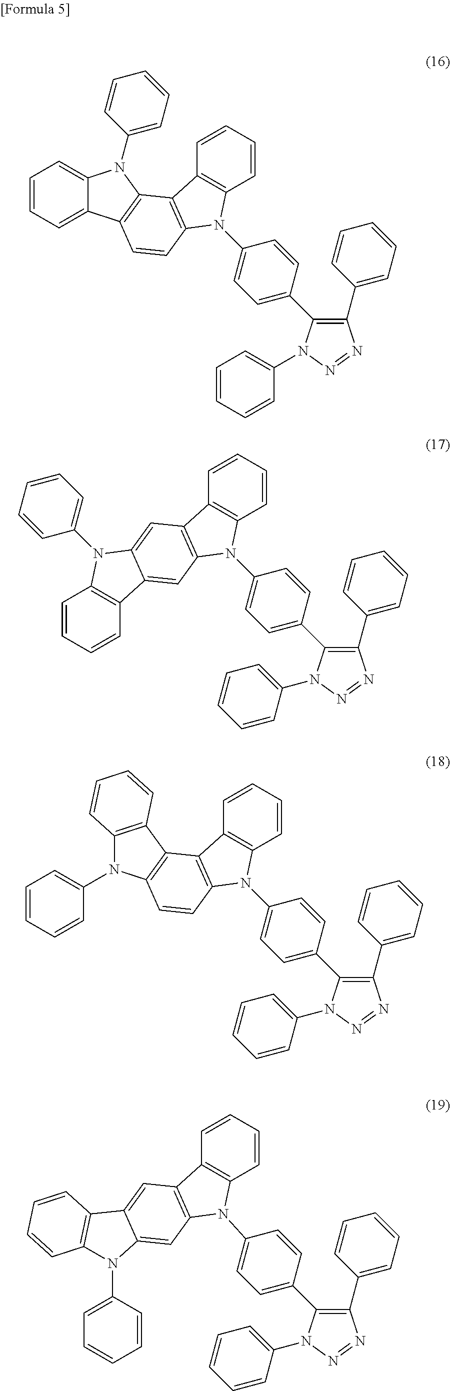

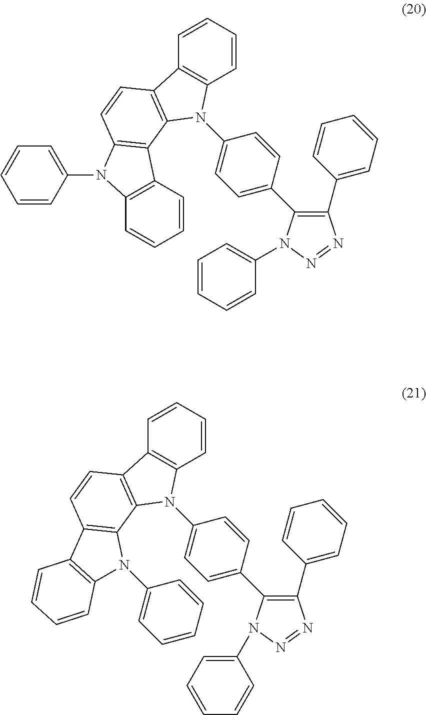 [SMILES: c1ccc(-c2nnn(-c3ccccc3)c2-c2ccc(-n3c4ccccc4c4ccc5c(c6ccccc6n5-c5ccccc5)c43)cc2)cc1 ; c1ccc(-c2nnn(-c3ccccc3)c2-c2ccc(-n3c4ccccc4c4ccc5c6ccccc6n(-c6ccccc6)c5c43)cc2)cc1]

According to an example embodiment, the charge transport material for an organic EL device may include, for example, the materials represented by the following Formula 6,

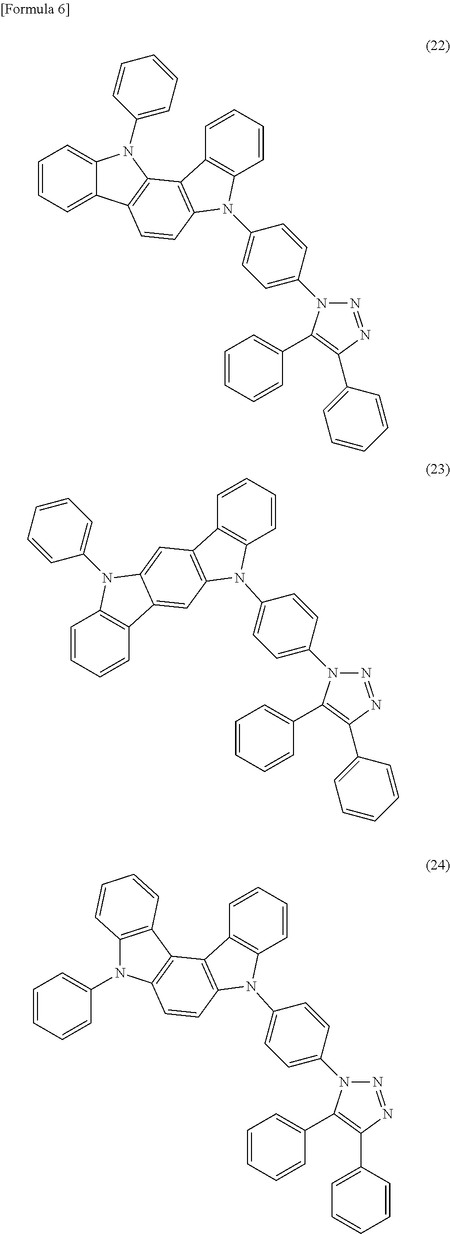 [SMILES: c1ccc(-c2nnn(-c3ccc(-n4c5ccccc5c5c4ccc4c6ccccc6n(-c6ccccc6)c45)cc3)c2-c2ccccc2)cc1 ; c1ccc(-c2nnn(-c3ccc(-n4c5ccccc5c5cc6c(cc54)c4ccccc4n6-c4ccccc4)cc3)c2-c2ccccc2)cc1 ; c1ccc(-c2nnn(-c3ccc(-n4c5ccccc5c5c6c7ccccc7n(-c7ccccc7)c6ccc54)cc3)c2-c2ccccc2)cc1]

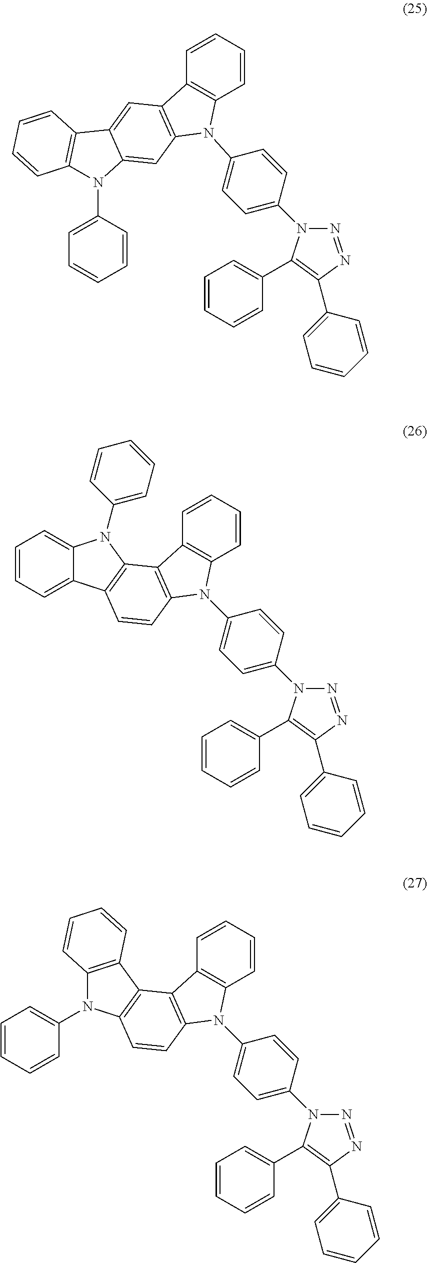 [SMILES: c1ccc(-c2nnn(-c3ccc(-n4c5ccccc5c5cc6c7ccccc7n(-c7ccccc7)c6cc54)cc3)c2-c2ccccc2)cc1 ; c1ccc(-c2nnn(-c3ccc(-n4c5ccccc5c5c4ccc4c6ccccc6n(-c6ccccc6)c45)cc3)c2-c2ccccc2)cc1 ; c1ccc(-c2nnn(-c3ccc(-n4c5ccccc5c5c6c7ccccc7n(-c7ccccc7)c6ccc54)cc3)c2-c2ccccc2)cc1]

According to an example embodiment, the charge transport material for an organic EL device may include, for example, the materials represented by the following Formula 7,

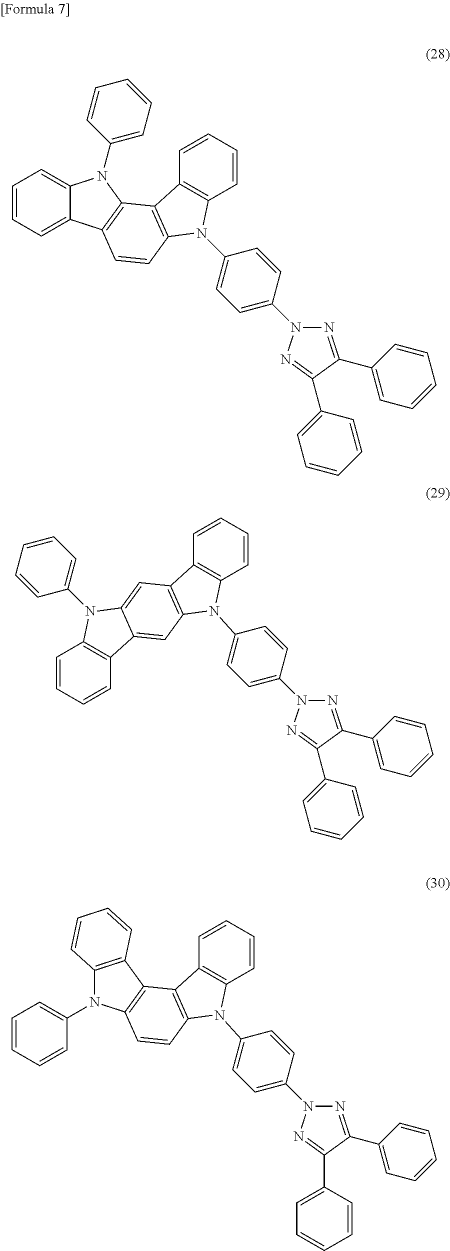 [SMILES: c1ccc(-c2nn(-c3ccc(-n4c5ccccc5c5c4ccc4c6ccccc6n(-c6ccccc6)c45)cc3)nc2-c2ccccc2)cc1 ; c1ccc(-c2nn(-c3ccc(-n4c5ccccc5c5cc6c(cc54)c4ccccc4n6-c4ccccc4)cc3)nc2-c2ccccc2)cc1 ; c1ccc(-c2nn(-c3ccc(-n4c5ccccc5c5c6c7ccccc7n(-c7ccccc7)c6ccc54)cc3)nc2-c2ccccc2)cc1]

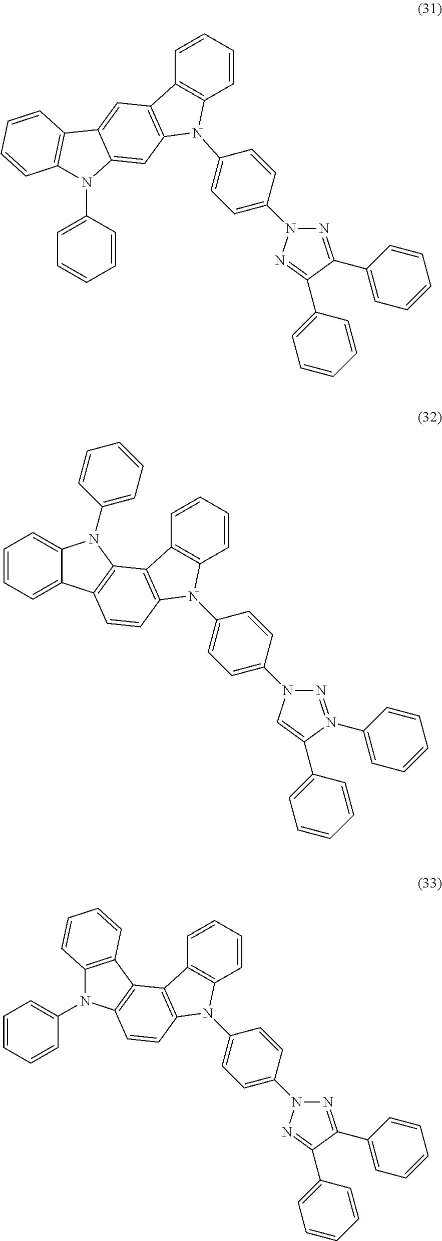

According to an example embodiment, the charge transport material for an organic EL device may include, for example, the materials represented by the following Formula 8,

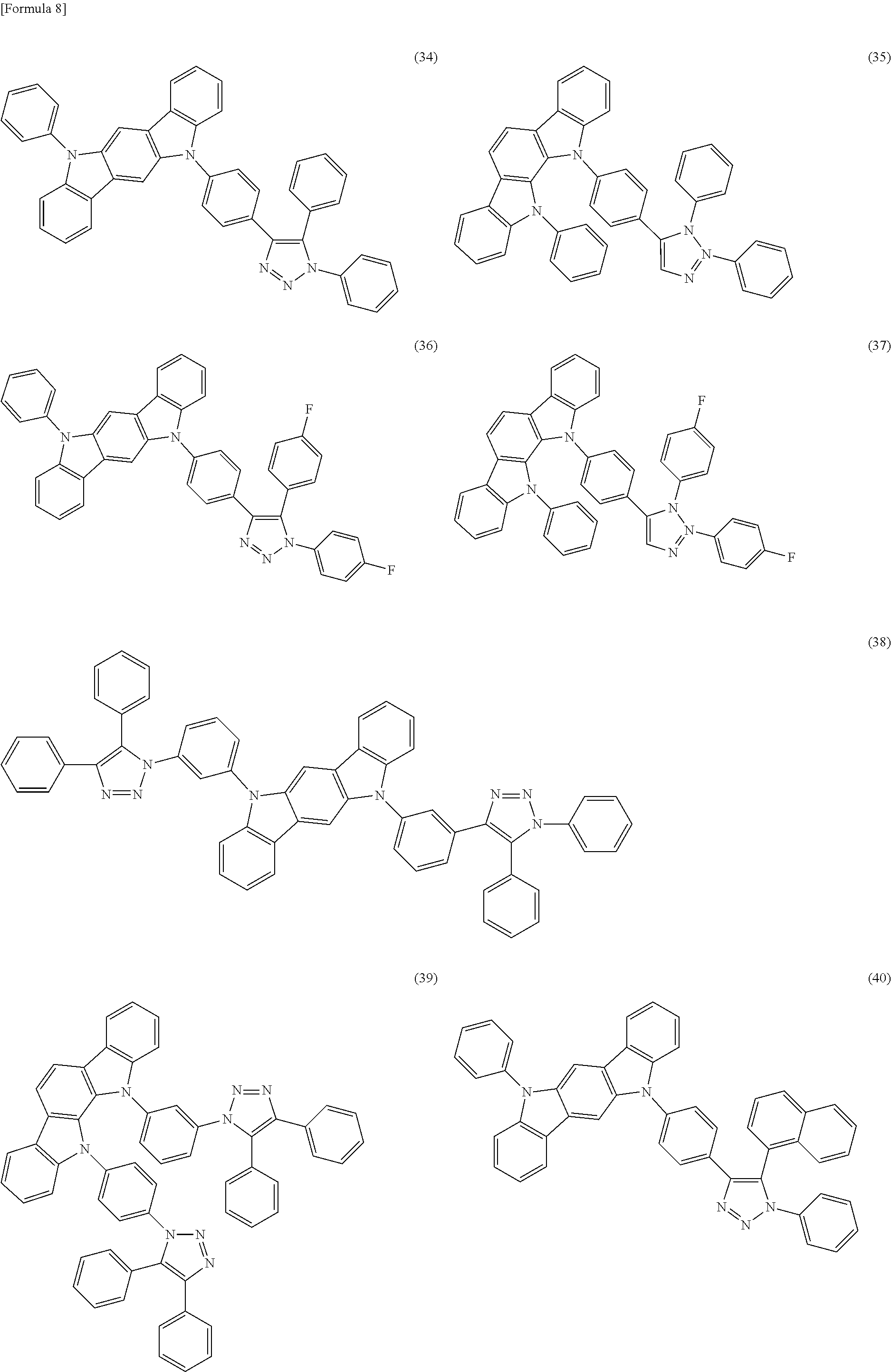

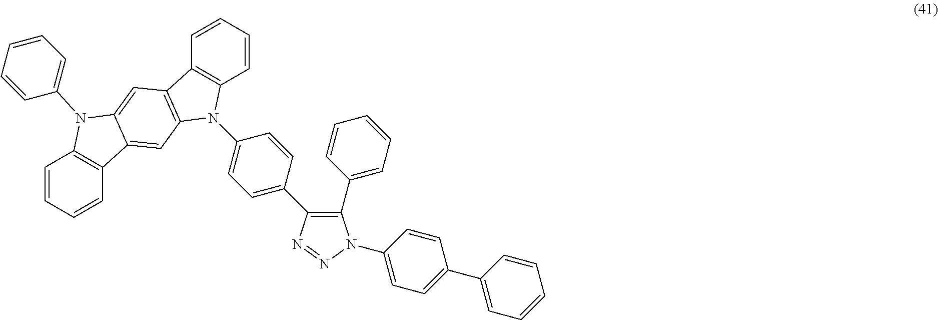 [SMILES: c1ccc(-c2ccc(-n3nnc(-c4ccc(-n5c6ccccc6c6cc7c(cc65)c5ccccc5n7-c5ccccc5)cc4)c3-c3ccccc3)cc2)cc1]

According to an example embodiment, the charge transport material for an organic EL device may include, for example, the materials represented by the following Formula 9,

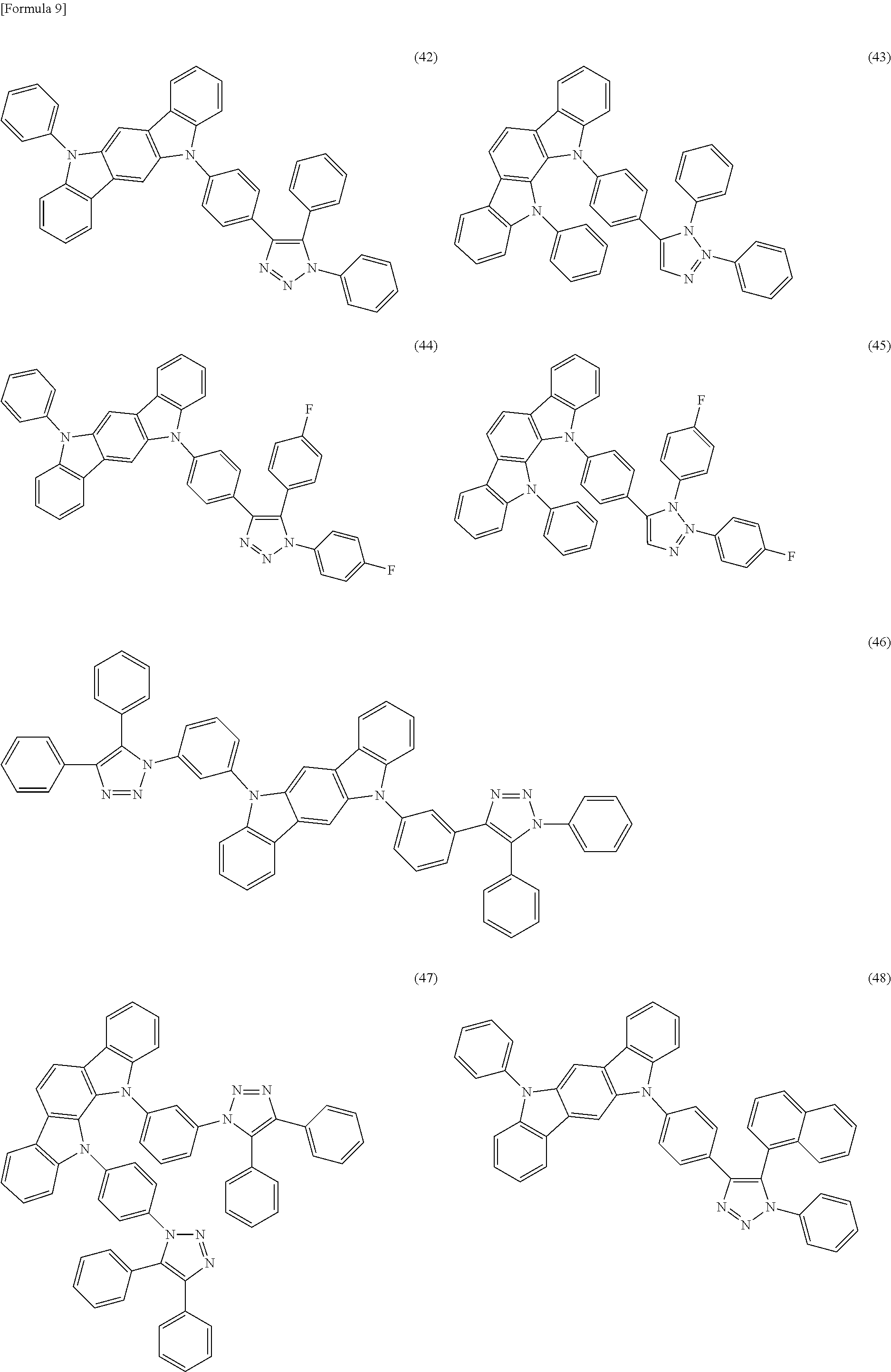

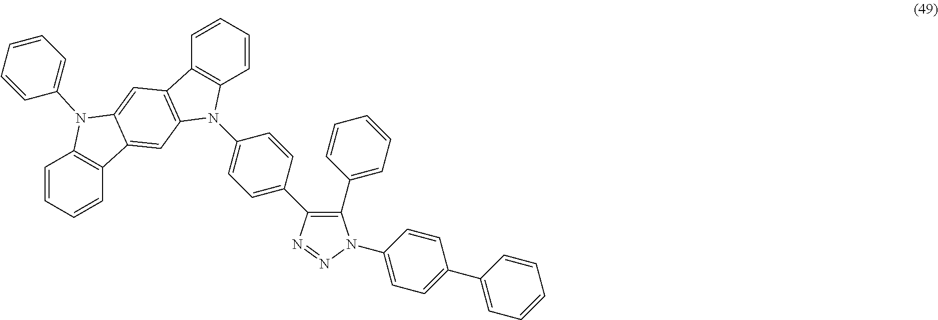 [SMILES: c1ccc(-c2ccc(-n3nnc(-c4ccc(-n5c6ccccc6c6cc7c(cc65)c5ccccc5n7-c5ccccc5)cc4)c3-c3ccccc3)cc2)cc1]

In the above example embodiments of charge transport materials for an organic EL device, an indolocarbazole skeleton having good hole transport properties and an azole skeleton having good electron transport properties by including a nitrogen atom having high electron affinity are combined. Thus, the manufacture of an emission layer having good properties such as the lowering of the voltage of an organic EL device may be possible. In addition, the triazole skeleton may have high triplet T1 energy, and light-emitting efficiency may be increased. Therefore, an organic El device including the emission layer using the illustrated charge transport material for an organic EL device may realize high light-emitting efficiency with a low driving voltage. In addition, longer life may be attained when compared to a general device.

Organic EL Device

Hereinafter an organic EL device manufactured by using the charge transport material for an organic EL device according to an example embodiment will be described.

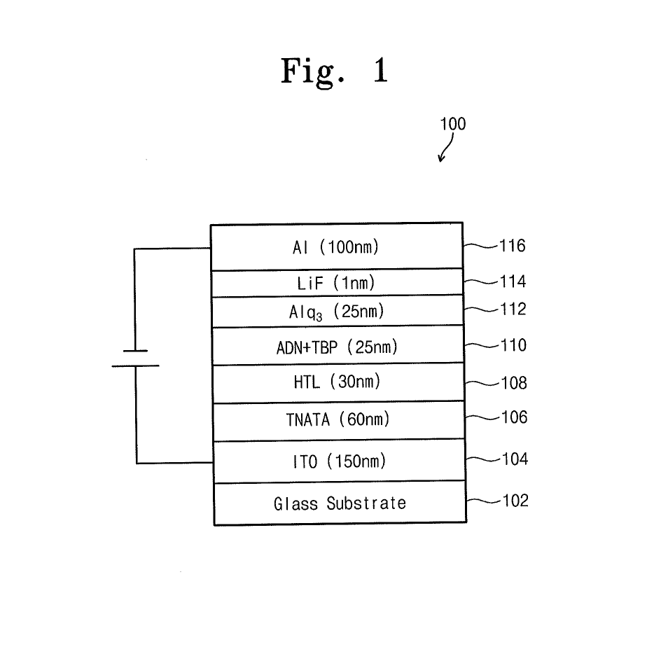

FIG. 1 is a schematic diagram illustrating an organic EL device 100 according to an example embodiment.

The organic EL device 100 may include, for example, a substrate 102, a positive electrode 104, a hole injection layer 106, a hole transport layer 108, an emission layer 110, an electron transport layer 112, an electron injection layer 114, and a negative electrode 116.

The substrate 102 may be, for example, a transparent glass substrate, a flexible substrate of a semiconductor substrate resin including silicon, and the like. The positive electrode 104 is disposed on the substrate 102, and may be formed by using indium tin oxide (ITO), indium zinc oxide (IZO), and the like. The hole injection layer 106 is disposed on the positive electrode 104, and may include 4,4′,4″-tris(N-1-naphthyl-N-phenyl-amino)triphenylamine (1-TNATA), and the like. The hole transport layer 108 is disposed on the hole injection layer 106, and may be formed by using, for example, α-NPD (N,N′-di-[(1-naphthyl)-N,N′-diphenyl-1,1′-biphenyl]-4,4′-diamine; NPB), N,N′-bis(3-methylphenyl)-N,N′-diphenylbenzidine (TPD), 4,4′-cyclohexylidenebis[N,N-bis(4-methylphenyl)benzeneamine] (TACP), a triphenyl tetramer, and the like. The emission layer 110 is disposed on the hole transport layer 108 and may be formed by doping, for example, tris(2-phenylpyridinato)iridium(III) (Ir(ppy)₃) or N,N,N′,N′-tetraphenylbenzidine (TPB) into the charge transport material, which is a host material. The electron transport layer 112 is disposed on the emission layer 110 and may be formed by using a material including, for example, tris(8-hydroxyquinolinato)aluminum (Alq₃). The electron injection layer 114 is disposed on the electron transport layer 112 and may be formed by using a material including, for example, lithium fluoride (LiF). The negative electrode 116 is formed on the electron injection layer 114 and may be formed by using a metal such as Al or a transparent material such as ITO, IZO, and the like.

An emission layer having improved electron transport properties, high efficiency and long life may be formed by using the charge transport material for an organic EL device according to an embodiment in the organic EL device 100. In addition, the charge transport material for an organic EL device may be applied in an organic EL apparatus of an active matrix using a thin film transistor (TFT).

### EXAMPLES

### Synthesis

The a charge transport material for an organic EL device according to an embodiment may be synthesized by, for example, the following Formula 10,

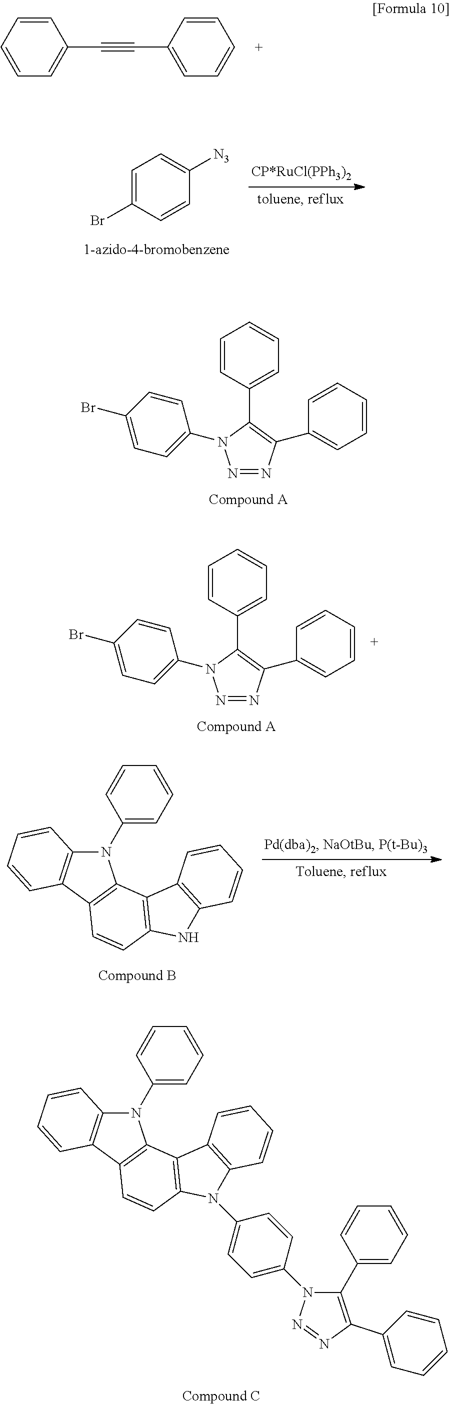

### Synthesis of Compound A

In a 500 ml reaction vessel equipped with an explosion proof plate, 1.78 g of diphenylacetylene, 47 mg of chloro(pentamethyl cyclopentadienyl)bistriphenylphosphineruthenium, and 200 ml of toluene were added, and under an inert atmosphere, 20 ml of a 0.5 M ethyl solution of 1-azido-4-bromobenzene was slowly added drop by drop while stirring at room temperature. After finishing the addition, the reactant was heated and stirred for 6 hours. After cooling to room temperature, the solution was concentrated, and purification by means of a silica gel column chromatography was conducted. 2.2 g of Compound A was obtained as a lemon yellow solid (FAB-MS (m/z) 375.04 (M+)).

### Synthesis of Compound C

Into a 100 ml reaction vessel, 1.0 g of indolocarbazole, 1.15 g of Compound A, 90 mg of palladiumbisdibenzalacetone, 0.87 g of sodium tert-butoxide, and 50 ml of toluene were added and stirred under an inert atmosphere at room temperature. Into the suspension thus obtained, 0.15 ml of a 2M toluene solution of tris tert-butylphosphine was added drop by drop and heated and refluxed for 24 hours. After finishing the reaction, extraction was performed using dichloromethane-water three times. An organic layer was concentrated and then purified by means of a silica gel chromatography to obtain 1.3 g of a target product (FAB-MS (m/z) 627.2 (M+)).

### Examples 1 to 3

Through performing the above-described preparation methods, three compounds illustrated in the following Formula 11 were produced,

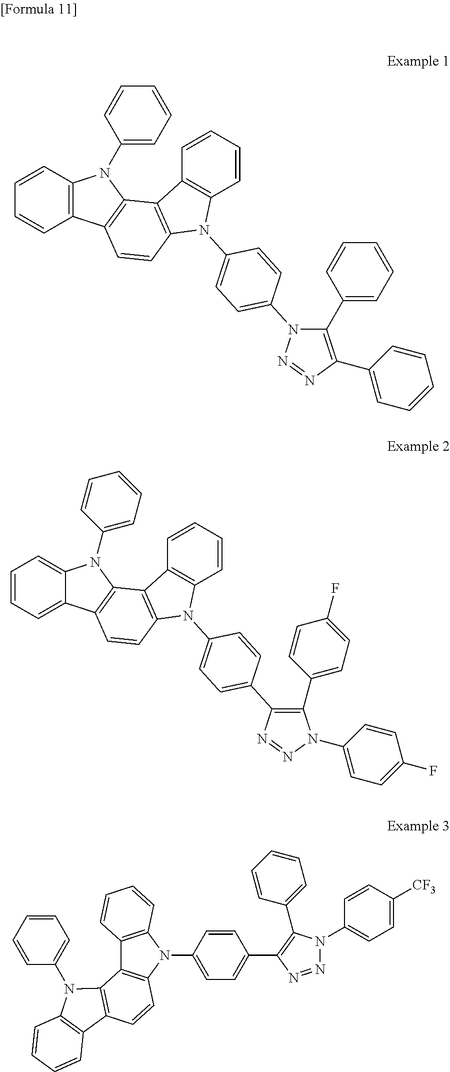 [SMILES: c1ccc(-c2nnn(-c3ccc(-n4c5ccccc5c5c4ccc4c6ccccc6n(-c6ccccc6)c45)cc3)c2-c2ccccc2)cc1 ; Fc1ccc(-c2c(-c3ccc(-n4c5ccccc5c5c4ccc4c6ccccc6n(-c6ccccc6)c45)cc3)nnn2-c2ccc(F)cc2)cc1 ; FC(F)(F)c1ccc(-n2nnc(-c3ccc(-n4c5ccccc5c5c4ccc4c6ccccc6n(-c6ccccc6)c45)cc3)c2-c2ccccc2)cc1]

### Comparative Example 1

As a comparative example, a compound illustrated in the following Formula 12 was prepared as a general carbazole material,

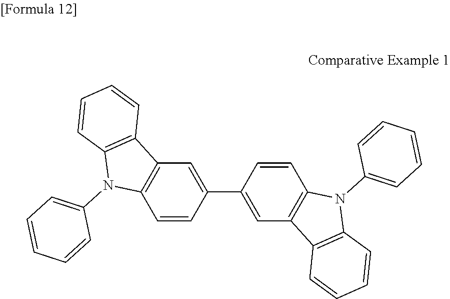 [SMILES: c1ccc(-n2c3ccccc3c3cc(-c4ccc5c(c4)c4ccccc4n5-c4ccccc4)ccc32)cc1]

Using the compounds of Examples 1 to 3, and Comparative Example 1 as charge transport materials, above-described organic EL devices were manufactured. The substrate was formed by using a transparent glass substrate, the positive electrode was formed by using ITO into a thickness of about 150 nm, and the hole injection layer was formed by using 1-TNATA into a thickness of about 60 nm. The hole transport layer was formed by using HMTPD into a thickness of about 30 nm, the emission layer obtained by doping Ir(ppy)₃ by 20% into the compounds of the above examples and comparative example was formed into a thickness of about 25 nm, the electron transport layer was formed by using Alq₃ into a thickness of about 25 nm, the electron injection layer was formed by using LiF into a thickness of about 1 nm, and the negative electrode was formed by using Al into a thickness of about 100 nm.

With respect to the manufactured organic EL devices, a voltage, current efficiency, and half-life were evaluated. The current efficiency was measured at about 10 mA/cm², and the half-life was measured at about 1,000 cd/m². The evaluation results are illustrated in the following Table 1,

TABLE 1

| | Voltage | Current | Half-life |
|---|---|---|---|
| | (V) | efficiency (cd/A) | (hr) |
| Example 1 | 4.9 | 35.5 | 1,600 |
| Comparative | 5.5 | 28.7 | 1,100 |
| Example 1 | | | |

As shown in Table 1, the organic EL device including the charge transport material of Example 1 was driven by a lower voltage than the organic EL device including the charge transport material of Comparative Example 1. The current efficiency for the device using the charge transport material of Example 1 was higher than that of the charge transport material of Comparative Example 1. With respect to the luminance half-life, the device using the charge transport material of Example 1 exhibited longer half-life when compared to the device using the charge transport material of Comparative Example 1.

In addition, when emission layers were formed by using the charge transport materials of Examples 1 to 3, white turbidity was not found in the emission layers. When using the charge transport material, a stable amorphous layer may be easily formed.

With respect to the compounds of Examples 1 to 3 and Comparative Example 1, electronic properties were examined by theoretical and chemical calculation, and the results are illustrated in the following Table 2,

TABLE 2

| | HOMO (eV) | LUMO (eV) | Triplet T1 energy |
|---|---|---|---|
| Example 1 | −5.10 | −1.26 | 2.96 |
| Example 2 | −4.98 | −1.33 | 2.95 |
| Example 3 | −4.96 | −1.27 | 2.94 |
| Comparative | −4.97 | −0.67 | 3.03 |
| Example 1 | | | |

Referring to Table 2, the same triplet T1 energy may be obtained when using the charge transport material of Examples 1 to 3 as that of the charge transport material of Comparative Example 1. These results indicate that the charge transport material is a practical material. Referring to LUMO, the charge transport materials of Examples 1 to 3 have quite high electron affinity and electron transport properties when compared to the charge transport material of Comparative Example 1.

As described above, the charge transport material for an organic EL device introduces a triazole structure in an indolocarbazole skeleton, and LUMO may be lowered, and electron affinity may be improved. In addition, the triplet T1 energy may be sufficiently high when the charge transport material according to an embodiment is used as the host material of phosphorescence. Without being bound by theory, it is believed that the formation of a stable amorphous thin layer may be enabled by introducing the triazole structure having low symmetry, and the charge transport material may be used as the host material of phosphorescence.

By way of summation and review, an example of a light-emitting device (herein referred to as an organic EL device) is an organic EL device that includes a positive electrode, a hole transport layer disposed on the positive electrode, an emission layer disposed on the hole transport layer, an electron transport layer disposed on the emission layer, and a negative electrode disposed on the electron transport layer. Holes injected from the positive electrode are injected into the emission layer via the hole transport layer. Meanwhile, electrons are injected from the negative electrode, and then injected into the emission layer via the electron transport layer. The holes and the electrons injected into the emission layer are recombined to generate excitons within the emission layer. The organic EL device emits a light by using a light generated by radiation and deactivation of the excitons. The organic EL device may have the above-described configuration or may be changed in various forms.

In application of the organic EL device to a display apparatus, high efficiency and long life of the organic EL device are desired, and for realizing the high efficiency and long life, normalization, stabilization and durability of the hole transport layer are considered.

As described above, embodiments relate to a charge transport material for an organic electroluminescence device having high efficiency and long life, and an organic electroluminescence device using the same. The charge transport material for an organic EL device according to an embodiment may provide good charge transport properties, and an organic EL device having high efficiency and long life may be manufactured by using the charge transport material.

In the charge transport material for an organic EL device according to an embodiment, R₃ and R₄ represent a phenyl group combined with the carbon atom or the nitrogen atom represented by the Ys, and an adjacent aryl group may be twisted by steric hindrance, and an emission layer of an amorphous layer having deteriorated planarity may be formed. A charge transport material for an organic EL device according to an example embodiment includes a triazole skeleton, and an organic EL device having good charge transport properties, high efficiency, long life, and a low driving voltage may be manufactured.

The organic EL device according to an example embodiment may include an emission layer having high efficiency by including the above-described structure, which may have good charge transport properties. In the organic EL device according to an example embodiment, R₃ and R₄ represent a phenyl group combined with the carbon atom or the nitrogen atom represented by the Ys, and an adjacent aryl group may be twisted by steric hindrance, and an emission layer of an amorphous layer having deteriorated planarity may be formed. An organic EL device according to an example embodiment includes a triazole skeleton, which may have good charge transport properties, and may include an emission layer having high efficiency, long life, and a low driving voltage.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A charge transport material for an organic electroluminescence device, comprising a combined structure obtained by condensing a skeleton represented by compound (1) and a skeleton represented by compound (2), the skeleton represented by compound (2) being combined with a skeleton represented by compound (3) while disposing an Ar included in the skeleton represented by compound (2) therebetween, in following Formula 1: 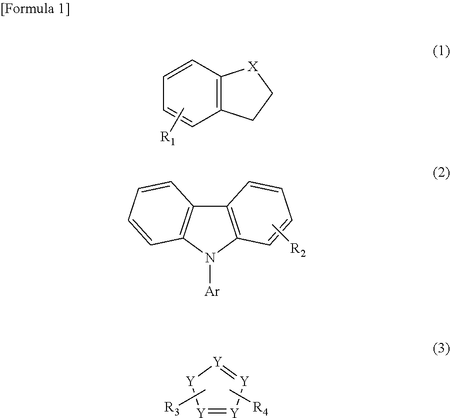
where X is oxygen, sulfur, or nitrogen combined with a substituted or unsubstituted, and straight or branched alkyl group, an aromatic group, or a heteroaromatic group having 1 to 10 carbon atoms,
R₁ is a substituted or unsubstituted, and straight or branched alkyl group, an aromatic group or a heteroaromatic group having 1 to 10 carbon atoms,
Ar is a single bond, a substituted or unsubstituted arylene group, or a heteroarylene group,
R₂ is a substituted or unsubstituted, and straight or branched alkyl group, an aromatic group or a heteroaromatic group having 1 to 10 carbon atoms,
each Y is a carbon atom or a nitrogen atom, at least three of the Ys being nitrogen atoms,
each of R₃ and R₄ independently represents a substituted or unsubstituted, and straight or branched alkyl group, an aromatic group or a heteroaromatic group having 1 to 10 carbon atoms, or a hydrogen atom,
a number of R₁ is 0 to 4,
a number of R₂ is 0 to 6, and
R₂ is combined with one ring or both rings among two benzene rings of compound (2).

2. The charge transport material as claimed in claim 1, wherein R₃ and R₄ in compound (3) include a phenyl group combined with the carbon or the nitrogen represented by the Ys.

3. The charge transport material as claimed in claim 1, wherein three of the Ys in compound (3) are the nitrogen atoms, and the nitrogen atoms are adjacent to each other.

4. An organic electroluminescence device comprising an emission layer formed by using a charge transport material for an organic electroluminescence device, the charge transport material comprising a combined structure obtained by condensing a skeleton represented by compound (4) and a skeleton represented by compound (5), the skeleton represented by compound (5) being combined with a skeleton represented by compound (6) while disposing an Ar included in the skeleton represented by compound (5) therebetween, in following Formula 2: 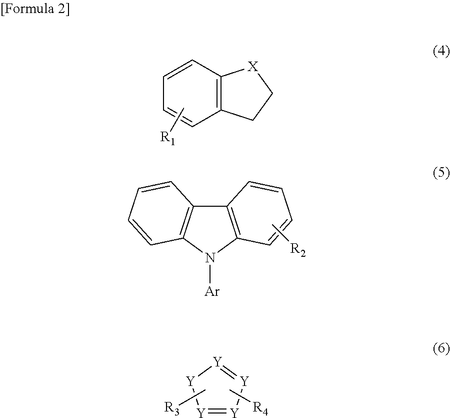
where X is oxygen, sulfur, or nitrogen combined with a substituted or unsubstituted, and straight or branched alkyl group, an aromatic group, or a heteroaromatic group having 1 to 10 carbon atoms,
R₁ is a substituted or unsubstituted, and straight or branched alkyl group, an aromatic group or a heteroaromatic group having 1 to 10 carbon atoms,
Ar is a single bond, a substituted or unsubstituted arylene group, or a heteroarylene group,
R₂ is a substituted or unsubstituted, and straight or branched alkyl group, an aromatic group or a heteroaromatic group having 1 to 10 carbon atoms,
each Y is a carbon atom or a nitrogen atom, at least three of the Ys being nitrogen atoms,
each of R₃ and R₄ independently represents a substituted or unsubstituted, and straight or branched alkyl group, an aromatic group or a heteroaromatic group having 1 to 10 carbon atoms, or a hydrogen atom,
a number of R₁ is 0 to 4,
a number of R₂ is 0 to 6, and
R₂ is combined with one ring or both rings among two benzene rings of compound (5).

5. The organic electroluminescence device as claimed in claim 4, wherein R₃ and R₄ in compound (6) include a phenyl group combined with the carbon or the nitrogen represented by the Ys.

6. The organic electroluminescence device as claimed in claim 4, wherein three of the Ys in compound (6) are the nitrogen atoms, and the nitrogen atoms are adjacent to each other.
